(19) United States
(12) Patent Application Publication
(10) Pub. No.: US 2007/0199592 A1
(43) Pub. Date: Aug. 30, 2007

(54) Solar cell string and solar cell module

(75) Inventors: Takaaki Agui, Nara-shi (JP); Naoki Takahashi, Soraku-gun (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/706,400

(22) Filed: Feb. 15, 2007

(30) Foreign Application Priority Data
Feb. 24, 2006 (JP) 2006-048823 (P)

(51) Int. Cl. H01L 31/00

(52) U.S. Cl. 136/256

(57) ABSTRACT

There are provided a solar cell string including a plurality of connected solar cells, each solar cell including a multilayered body having a photoelectric conversion layer, a first electrode formed on the multilayered body, a second electrode formed on the multilayered body, a first interconnector connected to the first electrode, and a second interconnector connected to the second electrode, wherein, in the solar cells adjacent to each other, the first interconnector connected to the first electrode of a first solar cell and the second interconnector connected to the second electrode of a second solar cell are connected via an intermediate member; and a solar cell module including the solar cell string.

This nonprovisional application is based on Japanese Patent Application No. 2006-048823 filed with the Japan Patent Office on Feb. 24, 2006, the entire contents of which are hereby incorporated by reference.

### BACKGROUND OF THE INVENTION

1. Field of the Invention

The present invention relates to a solar cell string and a solar cell module. In particular, the present invention relates to a solar cell string capable of reducing occurrence of deformation and breakage of an interconnector during the process of thinning a solar cell, and a solar cell module including the solar cell string.

2. Description of the Background Art

A compound semiconductor solar cell having a compound semiconductor layer stacked on a semiconductor substrate is a solar cell excellent in power generation efficiency and suitable for aerospace applications. When the compound semiconductor solar cell is used for aerospace purposes, it is important to reduce its mass. Accordingly, to form a thin and light-weight compound semiconductor solar cell, the semiconductor substrate which does not contribute to power generation is reduced in thickness, or is removed.

FIG. 13 shows a schematic cross section of a conventional compound semiconductor solar cell. A conventional compound semiconductor solar cell 100 has a multilayered body 111 including a plurality of compound semiconductor layers stacked on a semiconductor substrate 110. A first electrode 101 and a second electrode 102 are formed on multilayered body 111, to which an interconnector 103 and an interconnector 104 are connected, respectively. A transparent adhesive 113 is applied on multilayered body 111, and a protection film 112 is affixed thereon to protect multilayered body 111. Interconnectors 103 and 104 are each formed in a complicated shape to have a stress release function.

### SUMMARY OF THE INVENTION

In the conventional compound semiconductor solar cell having a structure shown in FIG. 13, however, thinning or removal of semiconductor substrate 110 should be performed with interconnectors 103 and 104 having a complicated shape each connected. Thereby, force is exerted on interconnectors 103 and 104, causing deformation and breakage of interconnectors 103 and 104.

In view of the above circumstances, one object of the present invention is to provide a solar cell string and a solar cell module capable of reducing occurrence of deformation and breakage of an interconnector during the process of thinning a solar cell.

The present invention is a solar cell string including a plurality of connected solar cells, each solar cell including a multilayered body having a photoelectric conversion layer, a first electrode formed on the multilayered body, a second electrode formed on the multilayered body, a first interconnector connected to the first electrode, and a second interconnector connected to the second electrode, wherein, in the solar cells adjacent to each other, the first interconnector connected to the first electrode of a first solar cell and the second interconnector connected to the second electrode of a second solar cell are connected via an intermediate member.

In the solar cell string of the present invention, the intermediate member can have a stress release function. A stress release function refers to a function to reduce force exerted on a junction between a solar cell and an interconnector when the distance between adjacent solar cells connected by the interconnector is changed in a solar cell string.

Further, in the solar cell string of the present invention, the first interconnector and the second interconnector may be disposed at displaced positions not facing each other.

Further, in the solar cell string of the present invention, the first solar cell may include a plurality of junctions between the first electrode and the first interconnector, and the second solar cell may include a plurality of junctions between the second electrode and the second interconnector.

Furthermore, the present invention is a solar cell module including the solar cell string described above.

According to the present invention, a solar cell string and a solar cell module capable of reducing occurrence of deformation and breakage of an interconnector during the process of thinning a solar cell can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view of one example of a solar cell constituting a solar cell string of the present invention.

FIG. 2 is a schematic cross sectional view illustrating a portion of a process of producing the solar cell shown in FIG. 1.

FIG. 3 is a schematic cross sectional view illustrating a portion of the process of producing the solar cell shown in FIG. 1.

FIG. 4 is a schematic cross sectional view illustrating a portion of the process of producing the solar cell shown in FIG. 1.

FIG. 5 is a schematic cross sectional view illustrating a portion of the process of producing the solar cell shown in FIG. 1.

FIG. 6 is a schematic cross sectional view illustrating a portion of the process of producing the solar cell shown in FIG. 1.

FIG. 7 is a schematic cross sectional view illustrating a portion of the process of producing the solar cell shown in FIG. 1.

FIG. 8 is a schematic top view of the solar cell shown in FIG. 1.

FIG. 9 is a schematic top view of one example of the solar cell string of the present invention.

FIG. 10 is a schematic top view of another example of the solar cell string of the present invention.

FIG. 11 is a schematic top view of another example of the solar cell string of the present invention.

FIG. 12 is a schematic top view of another example of the solar cell string of the present invention.

FIG. 13 is a schematic cross sectional view of a conventional compound semiconductor solar cell.

### DESCRIPTION OF THE PREFERRED EMBODIMENTS

Hereinafter, embodiments of the present invention will be described. In the drawings of the present invention, identical or corresponding parts will be designated by the same reference numerals.

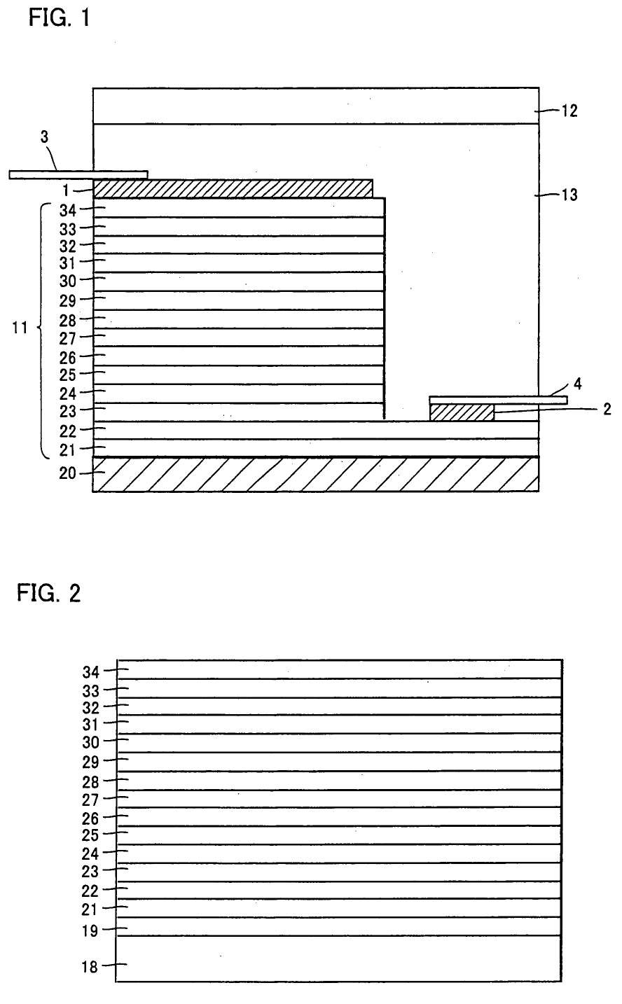

FIG. 1 is a schematic cross sectional view of one example of a solar cell constituting a solar cell string of the present invention. In the solar cell constituting the solar cell string of the present invention, a 0.02 μm-thick n-type InGaP layer 21 as a buffer layer, a 0.02 μm-thick n-type GaAs layer 22, a 0.02 μm-thick p-type AlGaAs layer 23, a 0.1 μm-thick p-type InGaP layer 24 as a back surface field layer, a 3 μm-thick p-type GaAs layer 25 as a base layer, a 0.1 μm-thick n-type GaAs layer 26 as an emitter layer, a 0.03 μm-thick n-type AlInP layer 27 as a window layer, a 0.02 μm-thick n-type InGaP layer 28, a 0.02 μm-thick p-type AlGaAs layer 29, a 0.03 μm-thick p-type AlInP layer 30 as a back surface field layer, a 0.5 μm-thick p-type InGaP layer 31 as a base layer, a 0.05 μm-thick n-type InGaP layer 32 as an emitter layer, a 0.03 μm-thick n-type AlInP layer 33 as a window layer, and a 0.5 μm-thick n-type GaAs layer 34 as a cap layer are stacked in this order on a metal film 20 to form a multilayered body 11 of the compound semiconductor layers. A first electrode 1 is formed on the surface of n-type GaAs layer 34, and a second electrode 2 is formed on the surface of n-type GaAs layer 22. A first interconnector 3 is electrically connected to the first electrode 1, and a second interconnector 4 is electrically connected to the second electrode 2. A transparent adhesive 13 is applied on the surface of multilayered body 11, and a protection film 12 is affixed thereon.

In this structure, n-type GaAs layer 22 and n-type InGaP layer 28 are each doped with an n-type dopant more heavily than other n-type compound semiconductor layers, and p-type AlGaAs layer 23 and p-type AlGaAs layer 29 are each doped with a p-type dopant more heavily than other p-type compound semiconductor layers. Thereby, n-type GaAs layer 22 and p-type AlGaAs layer 23 form a tunnel junction, and n-type InGaP layer 28 and p-type AlGaAs layer 29 form a tunnel junction.

Further, a layered body including p-type GaAs layer 25 and n-type GaAs layer 26 in contact with each other serves as a photoelectric conversion layer. Similarly, a layered body including p-type InGaP layer 31 and n-type InGaP layer 32 in contact with each other also serves as a photoelectric conversion layer.

A solar cell in such a structure can be produced, for example, as described below. Firstly, as shown in a schematic cross sectional view in FIG. 2, an n-type GaAs layer 19, n-type InGaP layer 21, n-type GaAs layer 22, p-type AlGaAs layer 23, p-type InGaP layer 24, p-type GaAs layer 25, n-type GaAs layer 26, and n-type AlInP layer 27 are epitaxially grown sequentially on a 50 mm diameter disk-shaped n-type GaAs substrate 18 doped with Si.

Next, n-type InGaP layer 28, p-type AlGaAs layer 29, p-type AlInP layer 30, p-type InGaP layer 31, n-type InGaP layer 32, n-type AlInP layer 33, and n-type GaAs layer 34 are epitaxially grown sequentially on n-type AlInP layer 27.

As to the conditions of the epitaxial growth, the temperature is set for example at about 700° C. Further, TMG (trimethylgallium) and AsH₃ (arsine), for example, can be used as materials for growing a GaAs layer. TMI (trimethylindium), TMG, and PH₃ (phosphine), for example, can be used as materials for growing an InGaP layer. TMA (trimethylaluminum), TMI, and PH₃, for example, can be used as materials for growing an AlInP layer.

Further, SiH₄ (monosilane), for example, can be used as a material of an impurity for forming an n-type GaAs layer, an n-type InGaP layer, and an n-type AlInP layer. DEZn (diethylzinc), for example, can be used as a material of an impurity for forming a p-type GaAs layer, a p-type InGaP layer, and a p-type AlInP layer.

Furthermore, TMA, TMG, and AsH₃, for example, can be used as materials for growing an AlGaAs layer, and CBr₄ (carbon tetrabromide), for example, can be used as a material of an impurity for forming a p-type AlGaAs layer.

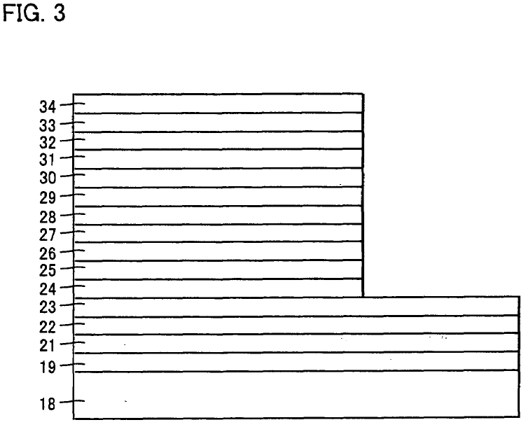

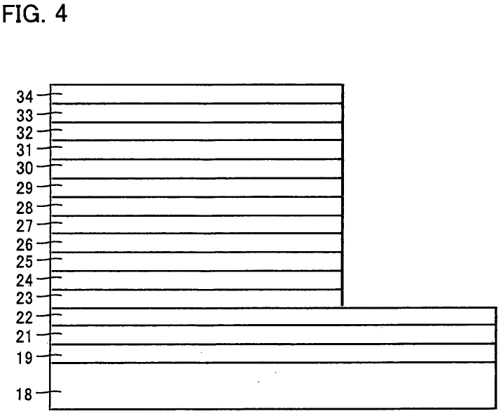

Subsequently, a resist is applied all over the surface of n-type GaAs layer 34. Then, for example photolithography is performed so that a portion of the resist is left and n-type GaAs layer 34 in a portion where the resist is not left is removed in a predetermined pattern by an etching solution such as an ammonia-based etching solution and an HCl-based etching solution, until the surface of p-type AlGaAs layer 23 is exposed, as shown in a schematic cross sectional view in FIG. 3. Thereafter, the exposed p-type AlGaAs layer 23 is removed for example by an HCl-based etching solution, as shown in a schematic cross sectional view in FIG. 4. Thereby, the surface of n-type GaAs layer 22 is exposed.

Subsequently, a resist pattern is formed for example by photolithography, and an Au—Ge film, an Ni film, an Au film, and an Ag film, for example, are sequentially deposited from above the resist pattern, to form a metal film.

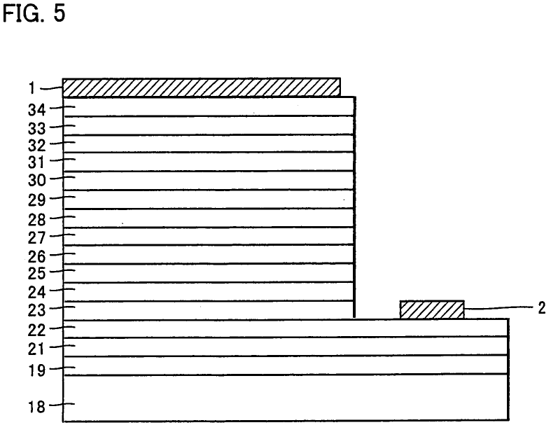

Next, the metal film formed on the resist pattern is removed together with the resist pattern, for example by a lift-off technique, and thereafter heat treatment is performed. Thereby, the first electrode I and the second electrode 2 shown in a schematic-cross sectional view in FIG. 5 can be formed simultaneously. Then, 50 mm diameter n-type GaAs substrate 18 is cut into square plates each having a width of 20 mm and a length of 20 mm, for example, to produce a wafer with the structure shown in FIG. 5.

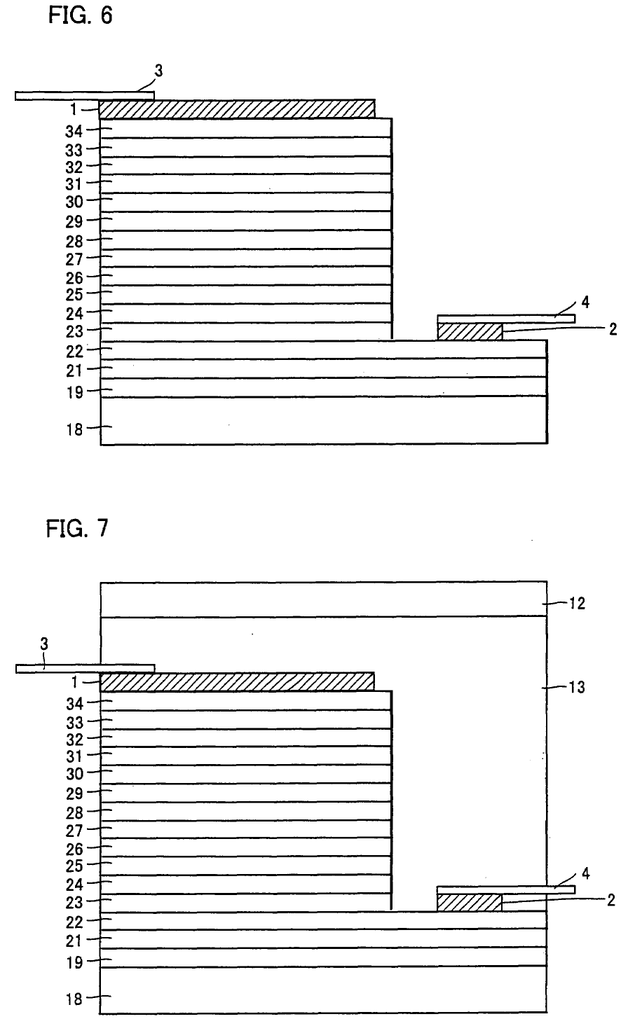

Subsequently, as shown in a schematic cross sectional view in FIG. 6, the first interconnector 3 in the shape of a short strip is electrically connected to the first electrode 1 of the wafer produced as described above, for example by welding, and the second interconnector 4 in the shape of a short strip is electrically connected to the second electrode 2 of the wafer, for example by welding.

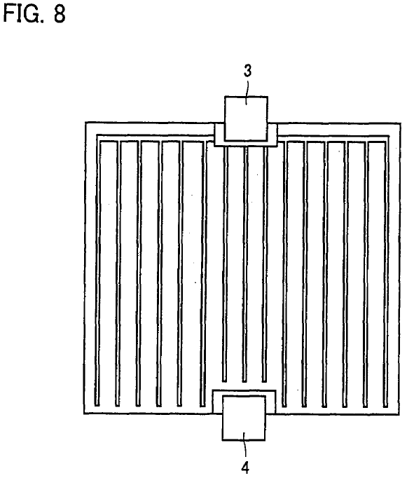

Then, as shown in a schematic cross sectional view in FIG. 7, transparent adhesive 13 for example made of silicone is applied, protection film 12 such as a PET (polyethylene terephthalate) film or a PEN (polyethylene naphthalate) film is affixed thereon, and protection film 12 is bonded by curing the transparent adhesive at a predetermined temperature.

Thereafter, the surface of protection film 12 is covered for example with a resist, and n-type GaAs substrate 18 and n-type GaAs layer 19 are removed for example by an ammonia-based etching solution. An Au film and an Ag film, for example, are sequentially deposited onto the exposed surface of n-type InGaP layer 21, and then heat treatment is performed to form metal film 20 all over the exposed surface of n-type InGaP layer 21. Thereby, the solar cell having the structure shown in FIG. 1 can be produced.

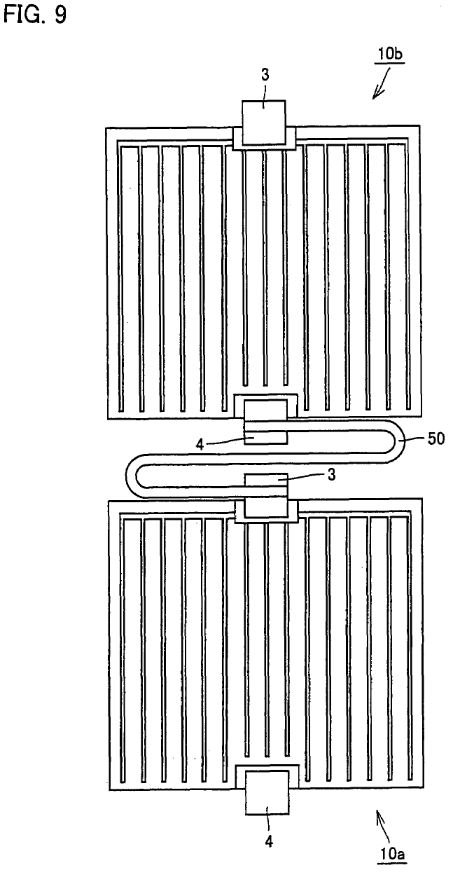

FIG. 8 shows a schematic top view of the solar cell shown in FIG. 1. A solar cell string of the present invention can be produced by preparing a plurality of solar cells each having such a structure, and, in two solar cells adjacent to each other, electrically connecting the first interconnector 3 connected to the first electrode of a first solar cell 10a and the second interconnector 4 connected to the second electrode of a second solar cell 10b, via an intermediate member 50 having the stress release function, for example, as shown in a schematic top view in FIG. 9. Further, a solar cell module of the present invention can be produced by sealing the solar cell string in a conventionally known transparent resin or the like.

As described above, in the present invention, thinning of the solar cell can be performed with only the interconnector having a simple shape such as a short strip connected, the interconnector being resistant to deformation and breakage during the process of thinning the solar cell. Further, the solar cell string and the solar cell module can be produced by connecting the above interconnectors of the thinned solar cells via the intermediate member. Therefore, in the present invention, occurrence of deformation and breakage of the interconnector during the process of thinning the solar cell can be reduced compared to a conventional solar cell.

Preferably, intermediate member 50 used in the present invention has the stress release function. When intermediate member 50 has the stress release function, there is a tendency that disconnection of the solar cells can be suppressed while the solar cell module is being produced and while the solar cell string and the solar cell module are being used.

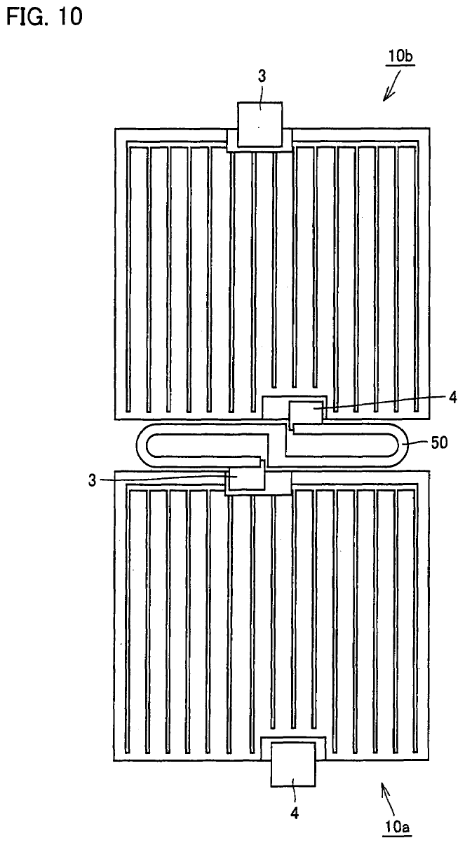

Further, by disposing the first interconnector 3 and the second interconnector 4 at displaced positions not facing each other, the solar cells can be mounted with a reduced interval therebetween, as shown in a schematic top view in FIG. 10. Specifically, in this case, even when the first interconnector 3 of the first solar cell 10a and the second interconnector 4 of the second solar cell 10b each project outward from the solar cells, the first interconnector 3 and the second interconnector 4 do not come into contact with each other. Thereby, the solar cell string and the solar cell module can be produced with a reduced interval between the first solar cell 10a and the second solar cell 10b. Accordingly, since the sunlight receiving area can be increased for each of the solar cell string and the solar cell module in this case, electric power generation tends to be increased.

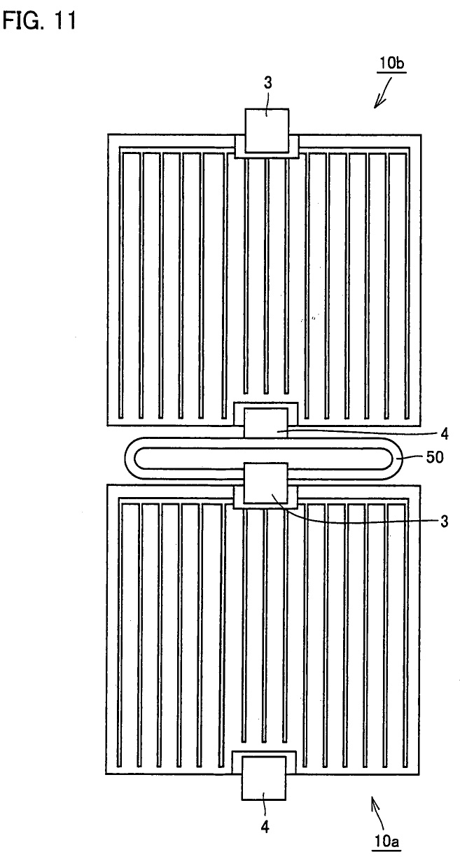

Furthermore, by changing the shape of intermediate member 50, the solar cells can be mounted with a reduced interval therebetween, as shown in a schematic top view in FIG. 11. Accordingly, since the sunlight receiving area can be increased for each of the solar cell string and the solar cell module also in this case, electric power generation tends to be increased. It is to be noted that intermediate member 50 shown in FIG. 11 is connected to the back side of the first interconnector 3 of the first solar cell 10a (the back side of the paper plane) and to the front side of the second interconnector 4 of the second solar cell 10b (the front side of the paper plane).

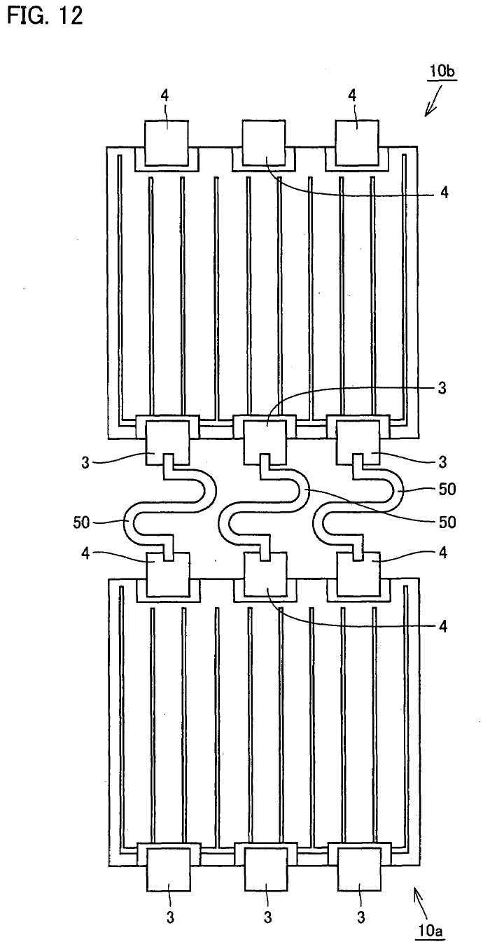

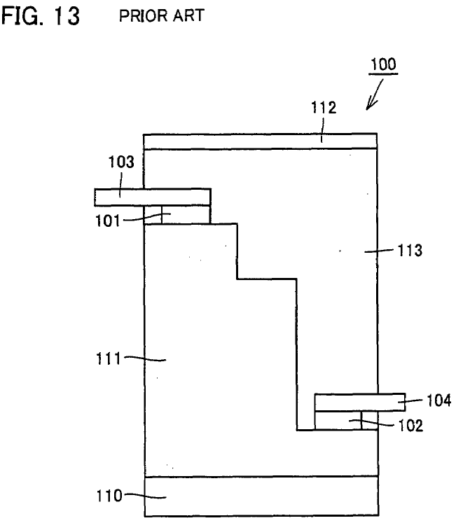

Further, in the solar cell string of the present invention, the first solar cell 10a may include a plurality of junctions between the first electrode 1 and the first interconnector 3, and the second solar cell 10b may include a plurality of junctions between the second electrode 2 and the second interconnector 4, as shown in a schematic top view in FIG. 12. With this structure, force exerted on a junction between the first electrode 1 and the first interconnector 3 and force exerted on a junction between the second electrode 2 and the second interconnector 4 each tend to be dispersed, reducing occurrence of deformation and breakage of the interconnector.

In the present invention, it is needless to say that the number of the semiconductor layers constituting the multilayered body as well as the materials and thicknesses of the semiconductor layers constituting the multilayered body are not limited to those described above.

Further, in the present invention, the materials of the first electrode and the second electrode are also not limited to those described above. In addition to an opaque conductive material such as a metal, a transparent conductive material such as ZnO (zinc oxide), SnO₂ (tin oxide), or ITO (Indium Tin Oxide) can also be used as a material of the first electrode and the second electrode. The first electrode and the second electrode have different polarities, that is, one of the electrodes has a positive polarity and the other has a negative polarity.

Furthermore, although the above description has been given on the case using a solar cell from which an n-type GaAs substrate, one example of a semiconductor substrate, is removed, a semiconductor substrate may be or may not be removed in the present invention.

In the present invention, the material of the first interconnector, the material of the second interconnector, and the material of the intermediate member are not limited specifically as long as each of them is a conductive material. Further, the shape of the first interconnector, the shape of the second interconnector, and the shape of the intermediate member are also not limited specifically. Preferably, the first interconnector and the second interconnector each have a shape such as a short strip to be resistant to deformation and breakage during the process of thinning the solar cell, and the intermediate member is shaped to have the stress release function as described above.

According to the present invention, a solar cell string and a solar cell module capable of reducing occurrence of deformation and breakage of an interconnector during the process of thinning a solar cell can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A solar cell string comprising a plurality of connected solar cells, each solar cell including a multilayered body having a photoelectric conversion layer, a first electrode formed on said multilayered body, a second electrode formed on said multilayered body, a first interconnector connected to said first electrode, and a second interconnector connected to said second electrode,
wherein, in said solar cells adjacent to each other, said first interconnector connected to said first electrode of a first solar cell and said second interconnector connected to said second electrode of a second solar cell are connected via an intermediate member.

2. The solar cell string according to claim 1, wherein said intermediate member has a stress release function.

3. The solar cell string according to claim 1, wherein said first interconnector and said second interconnector are disposed at displaced positions not facing each other.

4. The solar cell string according to claim 1, wherein said first solar cell includes a plurality of junctions between said first electrode and said first interconnector, and said second solar cell includes a plurality of junctions between said second electrode and said second interconnector.

5. A solar cell module comprising the solar cell string according to claim 1.
